(19) United States
(12) Patent Application Publication
(10) Pub. No.: US 2012/0024374 A1
(43) Pub. Date: Feb. 2, 2012

(54) Solar energy concentrator

(75) Inventors: Richard Morris Knox, Austin, TX (US); Chanda Bartlett Walker, Houston, TX (US)

(73) Assignee: RayDyne Energy, Inc., Austin, TX (US)

(21) Appl. No.: 13/200,225

(22) Filed: Sep. 21, 2011

Related U.S. Application Data
(63) Continuation-in-part of application No. 12/572,913, filed on Oct. 2, 2009.
(60) Provisional application No. 61/102,306, filed on Oct. 2, 2008.
(60) Provisional application No. 61/403,853, filed on Sep. 22, 2010.

(51) Int. Cl. H01L 31/0232; H01L 31/024

(52) U.S. Cl. 136/259

(57) ABSTRACT

A solar concentrator assembly comprises a segmented wave-guide assembly, a reflective mirror assembly, and an optical target-providing unit. A segmented waveguide assembly comprises a plurality of wave-guide segments, each segment comprising a set of surfaces disposed so as to support TIR propagation of solar energy and a turn mirror affixed thereto and disposed to receive solar energy from a mirror of the reflective mirror assembly and reflect said solar energy into the wave-guide segment at angles compatible with TIR propagation. The reflective mirror assembly comprises a plurality of mirrors each being aligned to reflect the solar energy to a turn mirror affixed to each wave-guide segment. The optical target providing unit converts solar energy from the light propagated in the wave-guide assembly to a different form of energy.

### CROSS-REFERENCE TO RELATED APPLICATIONS

This application is a Continuation-in-Part of pending U.S. patent application Ser. No. 12/572,913, published as 2010/0108124, filed Oct. 2, 2009, the entire contents whereof are incorporated into this application by reference herein and this application claims priority to U.S. Provisional Application Ser. No. 61/403,853, filed Sep. 22, 2010, the entire contents whereof are incorporated into this application by reference herein.

### FIELD OF THE INVENTION

The present invention relates to solar panels used to generate electrical or thermal power. More specifically the present invention relates to solar panels comprising an array of solar concentrators utilizing photovoltaic cells to generate electrical power.

### BACKGROUND OF THE INVENTION

Concentrators for solar energy have been in use for many years. These devices are used to focus the sun's energy into a small area to raise the power level being concentrated on a photovoltaic cell to generate electrical power directly, or on a fluid line to heat water to make steam to drive a turbine to generate electrical power.

One difficulty with these concentrators has been that they are generally large and bulky and are not suitable for residential applications or other locations where the aesthetics of the installation are of importance. Additionally they are very susceptible to environmental damage due to wind and other elements.

In a common implementation a refractive or reflective lens is used to focus the energy on a small photovoltaic cell. An example of a refractive device 100 is presented in FIG. 1 and shows a refractive lens 104 concentrating solar illumination 108 on a photovoltaic cell 112. This simple device concentrates light in a manner similar to the child's experiment wherein sunlight passing through a magnifying glass is focused onto a sheet of paper, thus setting it alight. Arrays of these are ganged together to generate greater amounts of power. An example of a reflective solar concentrator device 200 previously disclosed in FIG. 3 of U.S. Pat. No. 4,177,083, the contents whereof are incorporated by reference, is presented in FIG. 2. The optical principle is identical to that of a Cassegrain telescope first made known in the seventeenth century, with an energy conversion device replacing the eyepiece. Specifically, solar illumination 204 enters the device 200 and is reflected off of a main reflector 208 to a sub-reflector 212. The sub-reflector 212 reflects the illumination 204 to a photovoltaic cell 216. It suffers from the deficiency that the sub-reflector 212 blocks a substantial portion of the aperture of the main reflector 208 and thus decreases the ability of the device to concentrate light.

Stepped wave guides have long been known in the art. In U.S. Pat. No. 5,202,950, Arego et al, and U.S. Pat. No. 5,050,946, Hathaway et al, the contents of which are incorporated herein by reference in their entirety, one inventor of the present invention discloses a faceted light pipe and a light pipe system suitable to backlight a transmissive liquid crystal display from a single side light. In Arego et al, FIG. 8 depicts one embodiment of the light pipe further described in column 6, line 53, to column 7, line 58. FIG. 3 of this document repeats FIG. 8 previously referenced. In FIG. 3 the front surface portion 304 and the rear surface portion 308 of the light pipe 320 are substantially parallel. As stated in Arego et al these surfaces are specular surfaces so as to avoid diffuse reflections or refraction that make control of the light path more difficult. The light facet 312 is oriented at an angle α of 135° from the parallel rear surface portion 308. The light facets 312 are optionally coated with a reflective material 316, stated to be aluminum. The light facet 312 is designed to perform an angle transformation on light propagating in TIR mode within the light pipe 320 to allow that light to exit the light pipe 320 in order to provide illumination for the LCD.

FIG. 4 depicts an embodiment of the solar concentrator 400 disclosed in this application. The concentrator 400 includes a mirror assembly 404 to collect and concentrate solar radiation and to direct it to a set of turn mirrors 408 affixed to a stepped wave-guide 412. The turn mirrors 408 are arrayed so as to receive the solar radiation from the mirror assembly 404 and to reflect the solar radiation into the stepped wave-guide 412 at least partially using TIR between a plurality of parallel surfaces. The stepped wave-guide 412 captures the light redirected by the turn mirrors 408 so that the light propagates in TIR mode to a target. A Simple Parabolic Concentrator (SPC) 416 is optionally installed at the end of the propagation path of the stepped wave-guide 412 to further concentrate the captured light. Finally, a photovoltaic cell (PVC) can be affixed to the stepped wave-guide 412 or to the optional SPC 416 at the PVC mounting position 420 to convert the concentrated solar radiation to electrical energy.

As shown in FIG. 4, three axes of the system are defined. The longitudinal axis is the long axis of the solar concentrator 400. The transverse axis is the axis across the surface of the solar concentrator 400 orthogonal to the longitudinal axis. The solar axis is the axis orthogonal to the longitudinal and transverse axes and therefore orthogonal to the upper and lower surfaces of the stepped wave-guide 412.

Faceted light pipes like those disclosed by Arego, et al., have also been described in solar applications in U.S. Pub. No. 2009/0064993 to Ghosh et al. (Banyan). However, there remains a need for an improved system that can yield higher efficiency and be practically manufactured at a reasonable cost.

The cost advantages of a solar concentrator can best be realized if the concentration ratio is high. Highly efficient photovoltaic (PV) cells can efficiently convert a flux density equivalent to many hundreds of suns. Concentration ratios approaching 1000:1 and higher are considered desirable. The concentration goal is best determined after consideration of the technical and cost constraints a solar concentrator system must satisfy.

### SUMMARY OF THE INVENTION

A light concentrator in the form of a relatively thin, planar assembly takes sunlight in at an orientation normal to the planar surface and direct it via a plurality of small linear aspheric or spherical sections into a TIR (total internal reflection) light guide which collects and transports the sunlight from the linear aspheric sections to one edge of the light guide where it illuminates a solar photovoltaic cell or heats water or other medium. The illuminated point may be referred to as an optical target. As is well known in the art of light guides, TIR is the most efficient method for transporting light within a wave-guide. The efficiency of reflection is nominally 100% with the only losses coming from the transmission efficiency of the optical material. Optionally the solar energy may undergo an additional stage of concentration, for example through the use of a Simple Parabolic Concentrator (SPC) or similar device.

The concentrator of the present invention can include a plurality of aspheric mirror sections in a first stage, or element of concentration in the system. Each aspheric mirror section concentrates light by illuminating a turn mirror that redirects the light down a wave guide (light pipe) that relies upon Total Internal Reflection (TIR) and geometric optics to contain the light within the wave guide. In this application the wave-guide assembly is not co-extensive with the transverse axis of the mirror assembly but is rather substantially but perhaps not totally centered over the mirror assembly. The wave-guide assembly comprises a single optical assembly with multiple turn mirrors affixed thereto. In a different embodiment the wave-guide assembly comprises a series of loosely coupled optical layers each possessing a turn mirror that is associated with one of the reflector subsections on the mirror assembly. The resulting system will exhibit increased efficiency when the aperture blockage caused the presence of the light guide assembly is exceeded by the increase in efficiency due to the presence of a fully open aperture over the remainder of the reflector assembly. A disadvantage of the solar concentrator of FIG. 4 is the need to further concentrate light in a second stage along the transverse axis. This reduces the portion of the area of the total assembly over which solar radiation can be collected, thus resulting in the generation of less electrical power per unit area than would be the case if secondary concentration were not otherwise required.

A concentrator with very high gain and a method of constructing a concentrator using plastic extrusion and aluminum or silver metallization to produce low cost, thin concentrators with very high gain is described.

### BRIEF DESCRIPTION OF THE DRAWINGS

FIG. 1 depicts a known refractive solar concentrator.

FIG. 2 depicts a known reflective solar concentrator based on Cassegrain optics.

FIG. 3 is a depiction of a wave-guide from the backlight assembly of a flat panel liquid crystal display.

FIG. 4 is a previously disclosed solar concentrator.

FIG. 5 is an isometric depiction of a solar concentrator system and assembly after the present invention.

FIG. 6A is a plan view of a solar concentrator assembly without the photovoltaic cell assembly

FIG. 6B is a side view of a solar concentrator assembly without the photovoltaic cell assembly.

FIG. 7A is a simplified side view of a solar concentrator assembly

FIG. 7B is a simplified side view of one stage of a solar concentrator assembly.

FIG. 7C is a detailed view of a wave-guide assembly section and associated turn mirror.

FIG. 7D is a perspective depiction of a turn mirror affixed in close proximity to an angled surface at the extremity of a wave-guide segment;

FIG. 7E is a side depiction of a turn mirror affixed in close proximity to an angled surface at the extremity of a wave-guide segment;

FIG. 7F is a simplified side view of a turn mirror affixed in close proximity to an angled surface at the extremity of a wave-guide segment;

FIG. 7G is a simplified side view of a TIR mode ray trace inside a depiction of an external turn mirror affixed to an angled surface at the extremity of a wave-guide segment;

FIG. 7H depicts a simplified side view of a non-TIR ray trace inside a depiction of an external turn mirror affixed to an angled surface at the extremity of a wave-guide segment;

FIG. 8A is a detailed view of a single stage of a solar concentrator assembly.

FIG. 8B is a detailed view of a wave-guide support cradle.

FIG. 9A is a side view of three stages of a solar concentrator assembly after the present invention.

FIG. 9B is a side view of a single stage of a solar contractor assembly

FIG. 10A is an isometric depiction of the upper surface of two reflector assemblies with assembly hardware.

FIG. 10B is an expanded isometric view of a small number of mirror units from two reflector assemblies.

FIG. 10C is an isometric depiction of the under side of two reflector assemblies with assembly hardware.

FIG. 11A is an isometric depiction of a first embodiment of a photovoltaic cell assembly with photovoltaic cell attached

FIG. 11B is a view of a photovoltaic cell.

FIG. 11C is depiction of a photovoltaic cell assembly aligned to be mated to a solar concentrator assembly with light tunnels affixed thereto.

FIG. 11D is a view of an alternate embodiment of a photovoltaic cell assembly with light tunnel and mounting flange integral thereto.

FIG. 11E depicts the alternate embodiment of FIG. 11D mounted to a solar concentrator assembly.

FIG. 11F depicts and alternate configuration of a photovoltaic cell.

FIG. 12 is an expanded side view of one wave-guide support and alignment structure.

FIG. 13A presents an exploded view of a solar concentrator assembly unit.

FIG. 13B presents a view of an assembled solar concentrator assembly unit

FIG. 14 is a simplified electrical diagram of a plurality of solar concentrator assemblies within a solar concentrator assembly unit.

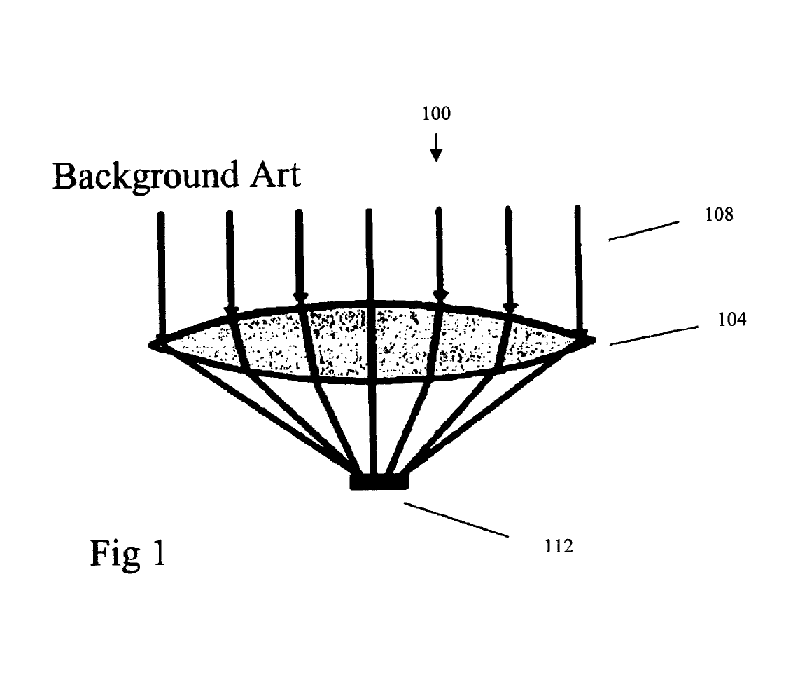

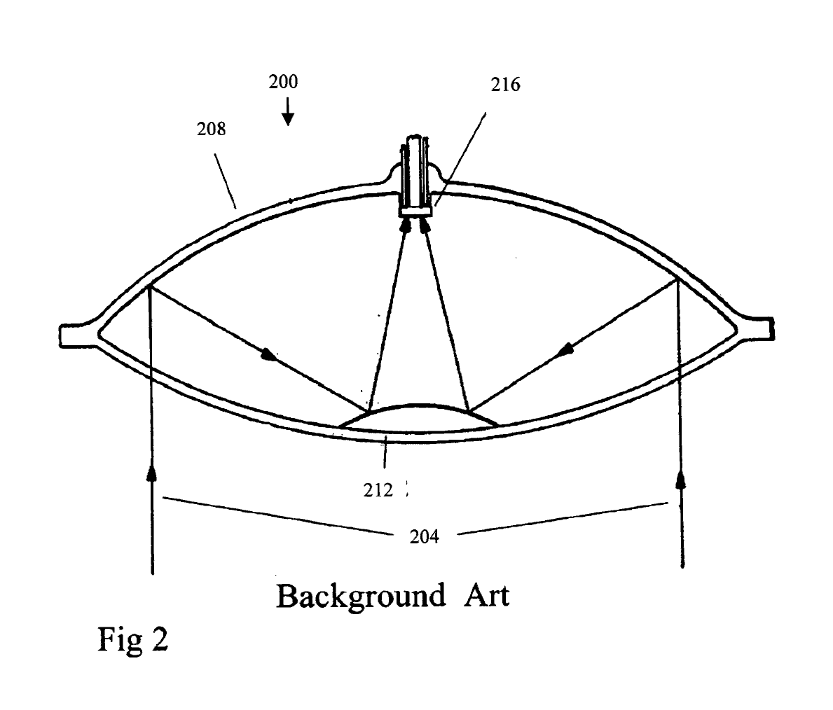

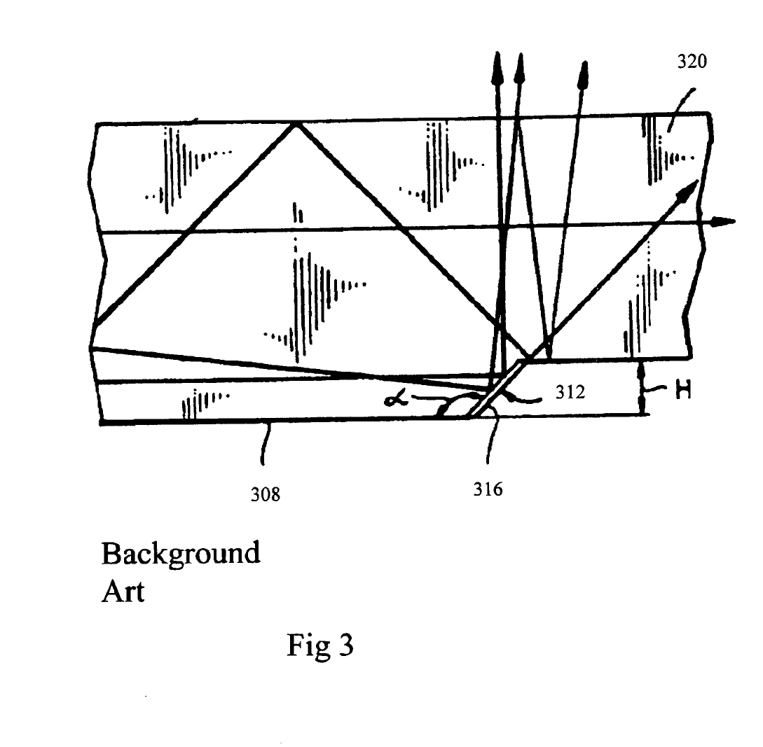

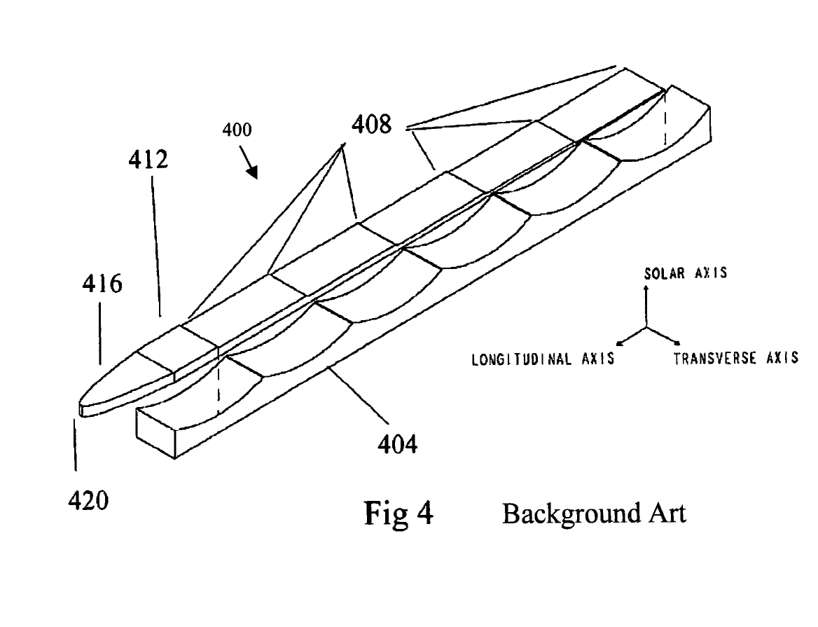

### DESCRIPTION OF THE INVENTION

In a pending patent application Ser. No. 12/572,306 the inventors of this invention disclose many aspects of the design and fabrication of solar energy concentrators and components thereof, the contents whereof are incorporated into this application by reference in its entirety.

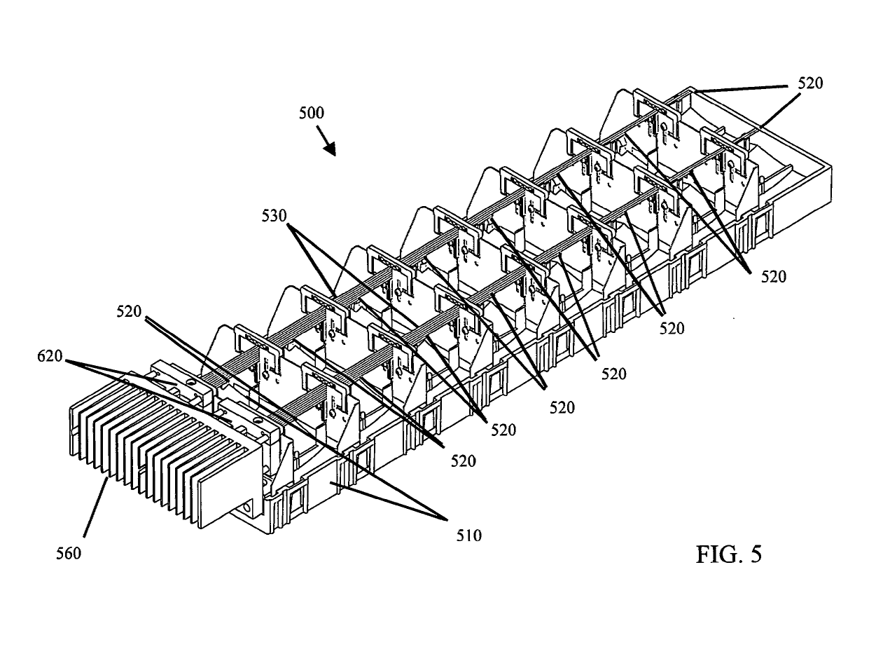

FIG. 5 depicts an embodiment of solar concentrator assembly 500 disclosed in this application. The solar concentrator system and assembly 500 includes mirror assembly 510 to collect and concentrate solar radiation and to direct it to a set of turn mirrors 520 affixed to the wave-guide assembly segments 535 (not shown) of wave-guide assembly 530. The turn mirrors 520 are arrayed so as to receive the solar radiation from the mirror assembly 510 and to reflect the solar radiation into the wave-guide assembly segment 535 to which it is affixed at least partially using TIR between a plurality of surfaces of the layer. The segments 535 of wave-guide assembly 530 capture the light redirected by the turn mirrors 520 so that the light propagates in TIR mode to a target. A photovoltaic cell (PVC) assembly 560 is coupled to wave-guide assembly 530 through light tunnel 620.

Mirror assembly 510 may be made of a choice of materials. Examples include cast metal, plastic molding, and PMMA acrylic. The individual mirror segments may be fabricated separately and then mounted to a suitable frame.

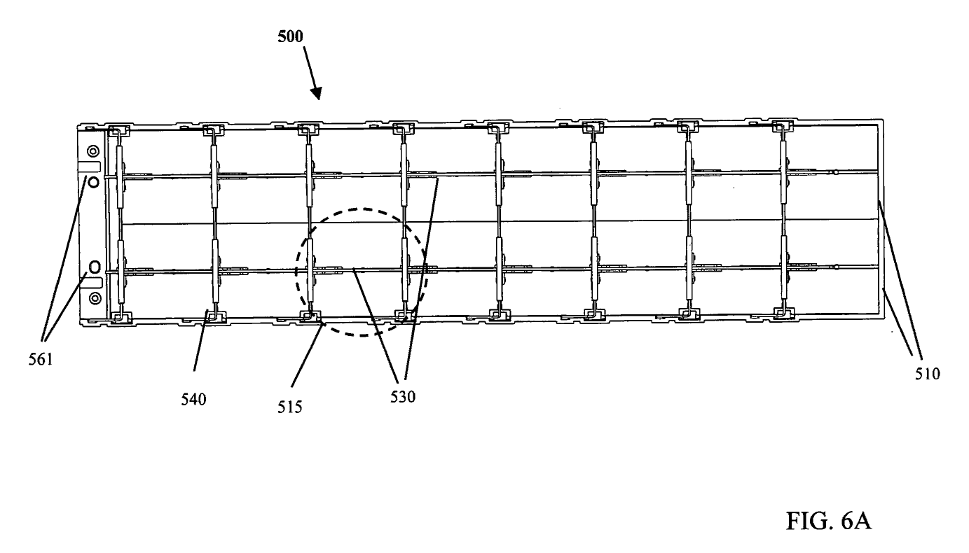

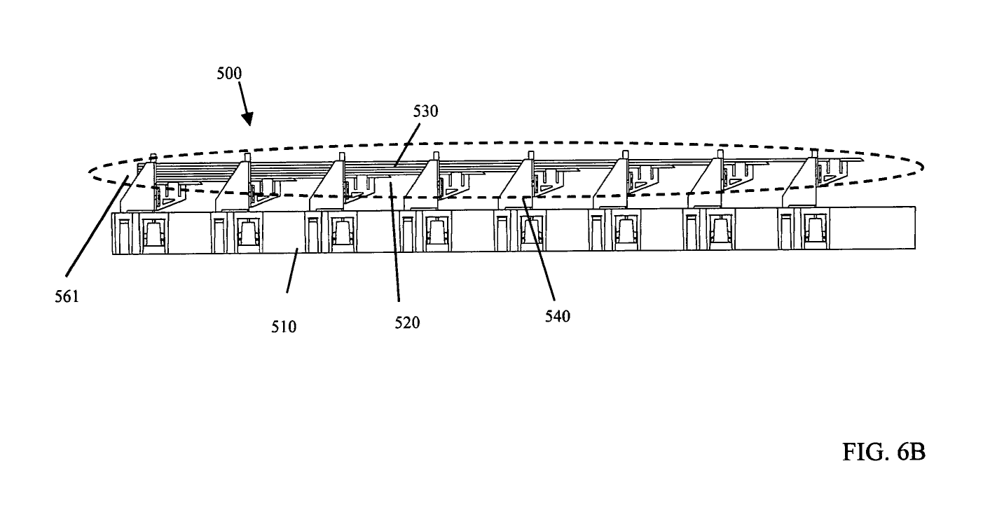

FIG. 6A depicts a plan view of solar concentrator assembly 500. FIG. 6A presents a two-channel system, although those familiar with the art of solar concentrators will understand that each channel is optically separate and a solar concentrator may comprise a fewer or greater numbers of channels. Mirror assemblies 510 comprises eight mirror segments 515 (one example circled) although those familiar with the art of solar concentrators will understand that a mirror assembly may comprise a fewer or greater number of mirror segments. Two instances of wave-guide assembly 530 are depicted, each comprised of wave-guide assembly segment 535 (not shown) with a turn mirror 520 affixed that is uniquely associated with one mirror segment 515. Wave-guide support riser 540 positions each segment 535 of the wave-guide assembly 530 in the correct position to receive solar energy reflected by each mirror segment 515 and additionally supports other wave-guide segments 535 that are above that segment. A photovoltaic cell assembly 560 (not shown) is installed at position 561 to receive the concentrated solar energy and convert said solar energy to electrical energy.

FIG. 6A is rendered to depict a width of mirror assembly 510 along the transverse axis that is far greater than the width of wave-guide assembly 530. The ratio of these two distances places an upper bound on the geometric concentration ratio along the transverse axis. Computer modeling reveals that a concentration ratio in the range of about 35 to about 40 along the transverse axis is possible.

FIG. 6B presents a side view of solar concentrator assembly 500. Wave-guide assembly 530 (encircled by the dashed oval) is positioned above mirror assembly 510 by wave-guide support riser 540. Individual turn mirrors 520 are located above each mirror assembly. A photovoltaic cell assembly 560 (not shown) is attached at mounting position 561.

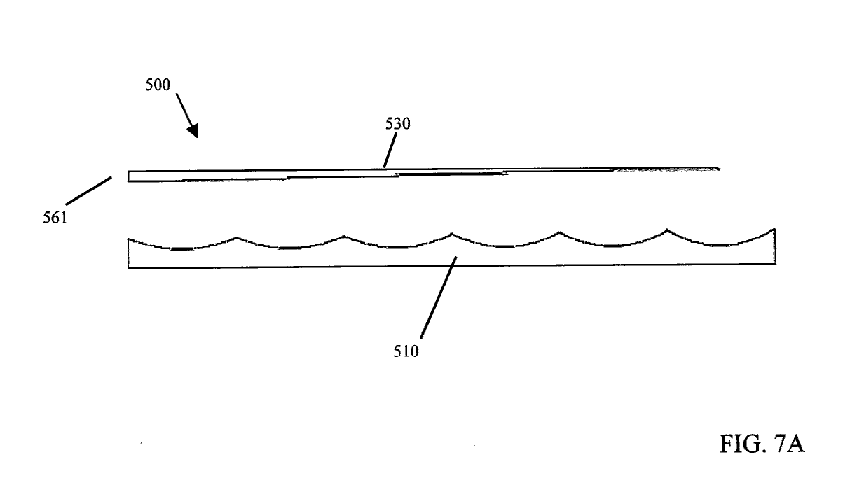

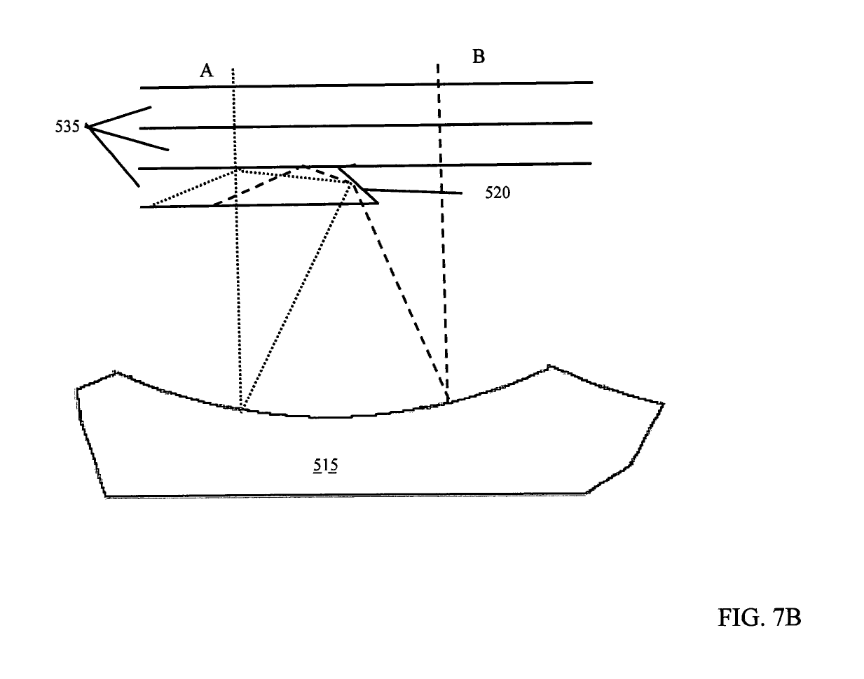

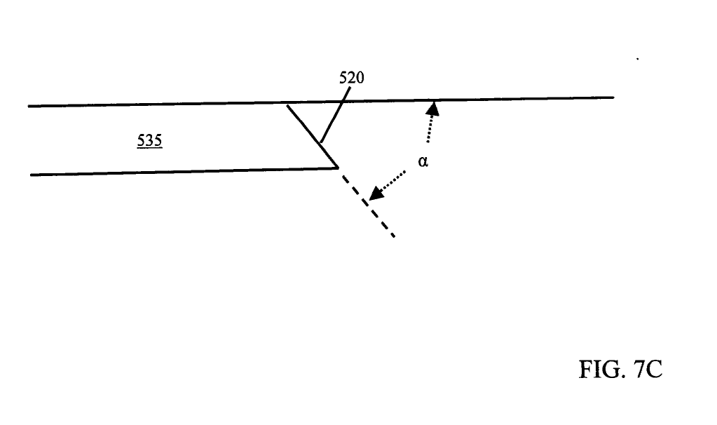

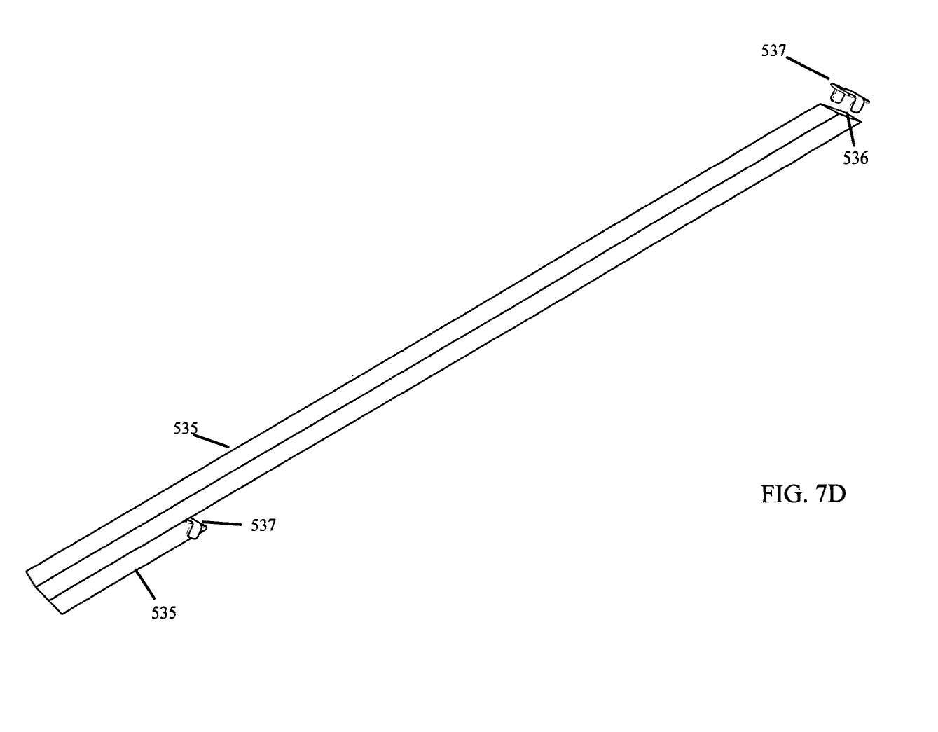

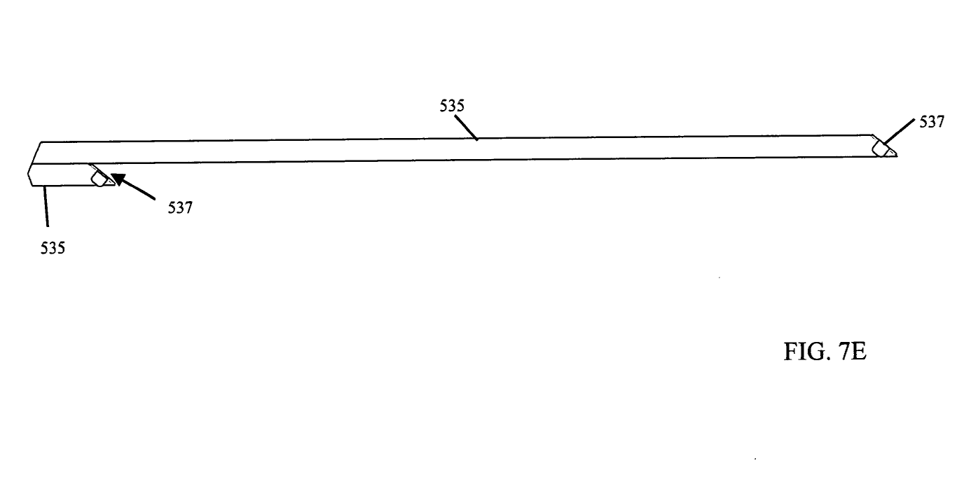

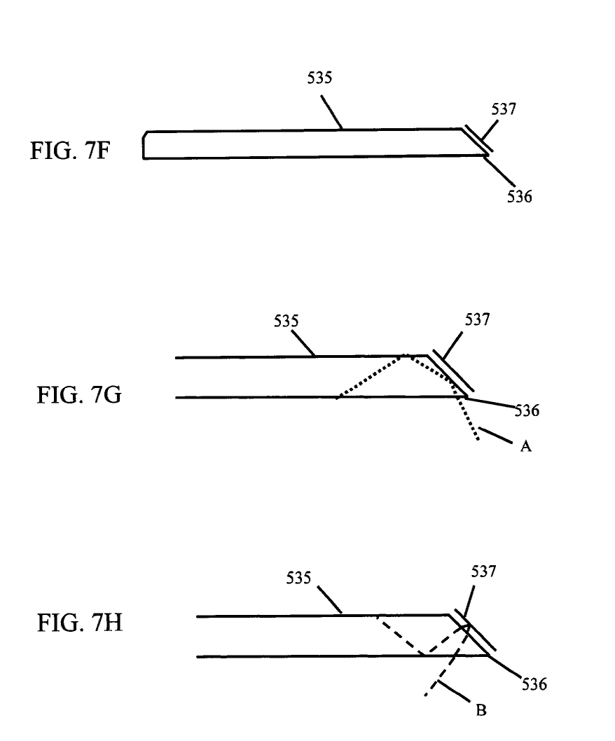

FIG. 7A presents a simplified side view of solar concentrator assembly 500. Wave-guide assembly 530 receives reflected light from a plurality of mirror segments 515 that form mirror assembly 510. Each mirror segment 515 of mirror assembly 510 is associated with a single wave-guide segment 535 (not shown). A photovoltaic cell assembly (not shown) is mounted at mounting position 561.

FIG. 7B presents one stage 590 of a solar concentrator assembly 500. Depicted are single mirror segment 515 and uniquely associated wave-guide segment 535 with turn mirror 520 affixed thereto. Other wave-guide segments 535 are also depicted that are uniquely associated with other mirror segments 515 (not shown). Ray traces A and B depict paths demonstrating the collection of solar radiation by mirror segment 515, reflection by turn mirror 520 allowing entry into wave-guide segment 535 and subsequent TIR propagation within wave-guide segment 535. Solar radiation collected by other mirror segments 515 propagates within associated wave-guide segment 535 in parallel to this wave-guide. Because of fresnel losses associated with the series of surfaces associated with wave guide segments 535 of wave-guide assembly 530 (not shown) ray traces A and B in reality are slight in front of or behind the apparent position.

FIG. 7C depicts a piece of a single wave-guide segment 535 with turn mirror 520 affixed thereto. Angle a represents the angle formed between wave-guide segment 535 and the edges of turn mirror 520. The edges of turn mirror 520 parallel to the transverse axis form a right angle to the longitudinal axis of wave-guide segment. A value for angle α is selected after modeling analysis of the need to present a turn mirror 520 target of sufficient size to capture as much light as possible from mirror segment 515 and reflect those rays of light at an angle sufficient to support TIR within wave-guide segment 535. In one embodiment angle α is approximately 45°. In another embodiment angle α is approximately 30°. Those of ordinary skill in the art will recognize the utility of other angles in this invention.

FIGS. 7D and 7E present an alternative means of implementing a turn mirror on wave-guide segment 535. Wave-guide segment 535 includes an angled surface 536 (shown at the right end only) at the end opposite the photovoltaic cell assembly (not shown). A separate turn mirror 537 is affixed to wave-guide 535 in close proximity and parallel to angled surface 536, preferably with a very small air gap on the order of at least 20 micrometers. Turn mirror 537 including its side tabs is preferably coated with a highly reflective mirror surface. The mirrored surfaces may be realized by sputtering silver or aluminum to the surface of turn mirror 537 or alternatively the surfaces may be coated with a dielectric stack as is well known in the art. The turn mirror is affixed by the tabs to the sides of wave-guide segment 535 by adhesive or other means.

FIG. 7F depicts use on wave-guide segment 535 of a turn mirror 537 separated from the angled surface 536 by a small air gap. Angled surface 536 is substantially parallel to external turn mirror 537. This facilitates two types of reflection. FIG. 7G depicts a ray trace A that satisfies the requirements to reflect from angled surface 536 in TIR mode and then TIR from the surfaces of wave-guide segment 535. The reflection from angled surface 536 will be at the highest possible efficiency. FIG. 7H depicts a ray trace B that does not satisfy the requirements to reflect from angled surface 536 in TIR mode. Ray trace B propagates across the air gap and is reflected by external turn mirror 537. Reflect ray trace B propagates back across the air gap and re-enters wave-guide segment 535 at angled surface 536. The refracted ray trace B now satisfies the requirements for TIR reflection and propagates through wave-guide segment 535 in that mode. The reflection from external turn mirror 537 will be of lesser efficiency than a TIR reflection.

In a simulation of an implementation of the present system mirror assembly 510 segments 515 are defined in the following data table:

| | | | | | Vertex of |
|---|---|---|---|---|---|
| Mirror | Longitudinal | Transverse | Radius of | Conic | Mirror |
| Segment | Length | Width | Curvature | Constant | Location |
| MS 1 | 45 | 45 | 58.883 | −0.964 | All mirror |
| MS 2 | 45 | 45 | 61.334 | −0.964 | vertices |
| MS 3 | 45 | 45 | 63.835 | −0.964 | are |
| MS 4 | 45 | 45 | 66.335 | −0.964 | located |
| MS 5 | 45 | 45 | 68.836 | −0.964 | 29 mm |
| MS 6 | 45 | 45 | 71.336 | −0.964 | below |
| MS 7 | 45 | 45 | 73.837 | −0.964 | the bottom |
| MS 8 | 45 | 45 | 76.337 | −0.964 | of the |
| | | | | | lowest |
| | | | | | wave- |
| | | | | | guide |
| | | | | | segment. |

All dimensions are in millimeters.

Where MS 1 is located closest to the photovoltaic cell and MS 8 is located at the end opposite the PVC assembly. Radius of curvature and conic constant are used in the following equation.

$$z = \frac{{cr}^{2}}{1 + \sqrt{1 - ( 1 + k ) {c}^{2} {r}^{2}}} + {\sum }_{i = 1}^{12} {α}_{i} {r}^{i}$$

Each wave-guide segment 535 is fabricated separately. The table below presents data for a set of wave-guide segments 535 and turn mirrors 520 that form a wave-guide assembly 530 to function with the mirror assembly 510 described in the previous table.

| Wave-Guide | Longitudinal | Transverse | | Turn Mirror |
|---|---|---|---|---|
| Segment | Length | Width | Thickness | Angle α |
| WGS 1 | 27.5 | 1.25 | 1.25 | 45° |
| WGS 2 | 67.5 | 1.25 | 1.25 | 45° |
| WGS 3 | 112.5 | 1.25 | 1.25 | 45° |
| WGS 4 | 157.5 | 1.25 | 1.25 | 45° |
| WGS 5 | 202.5 | 1.25 | 1.25 | 45° |
| WGS 6 | 247.5 | 1.25 | 1.25 | 45° |
| WGS 7 | 292.5 | 1.25 | 1.25 | 45° |
| WGS 8 | 337.5 | 1.25 | 1.25 | 45° |

All dimensions in mm

The reflector mirrors in the example cited above are each rotationally symmetric and formed as a square 45 millimeters on a side. Although nominally possessing identical concentration ratios the presence of the wave-guide assembly over mirror segments MS1 to MS7 along the longitudinal axis blocks the entire transverse aperture by a width of 1.25 millimeters and thus reduces the effective aperture available across the transverse axis by 1.25 millimeters. Thus the input aperture is effectively 45 mm×43.75 mm or 1968.75 square millimeters and the output aperture is 1.25 mm square or 1.5625 square millimeters. The ratio of these two factors reveals the limiting effective geometric concentration ratio of this example to be at least 1260. The wave-guide segment above MS 8 extends only half way across and is only one layer thick and therefore presents less of an impediment to the transmission of solar radiation. Therefore the input aperture is 2025 square millimeters. In this case the limiting geometric concentration ratio is 2025 sq mm divided by 1.25 mm squared or 1296.

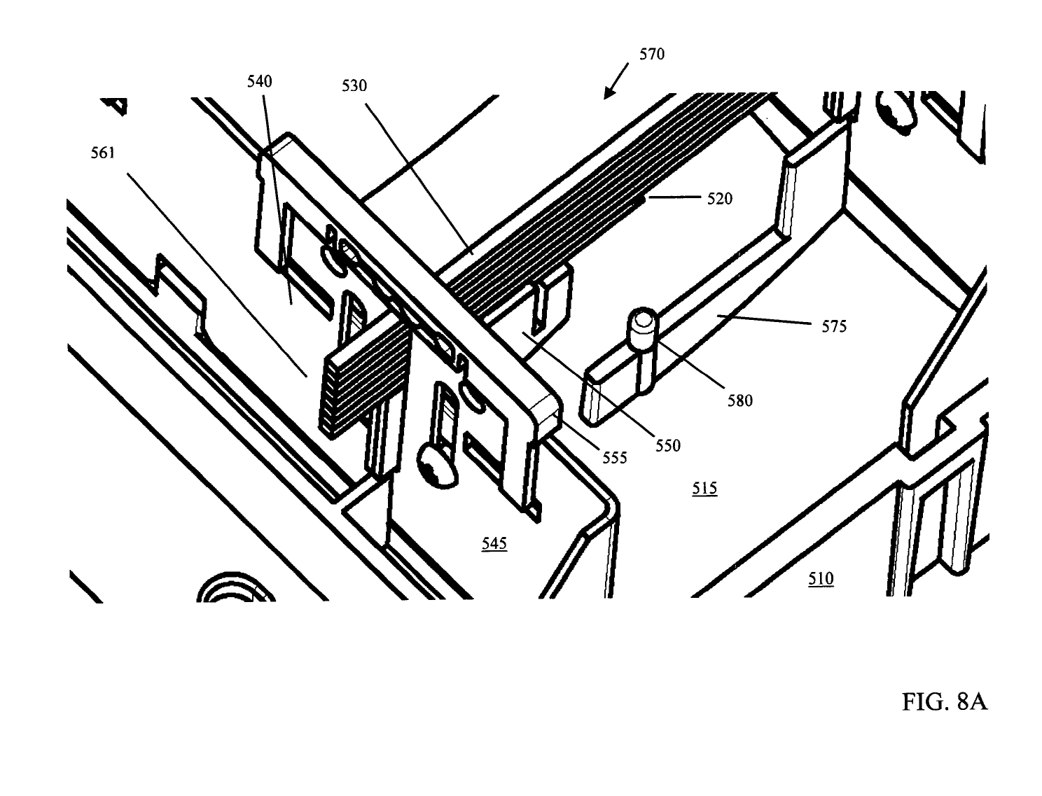

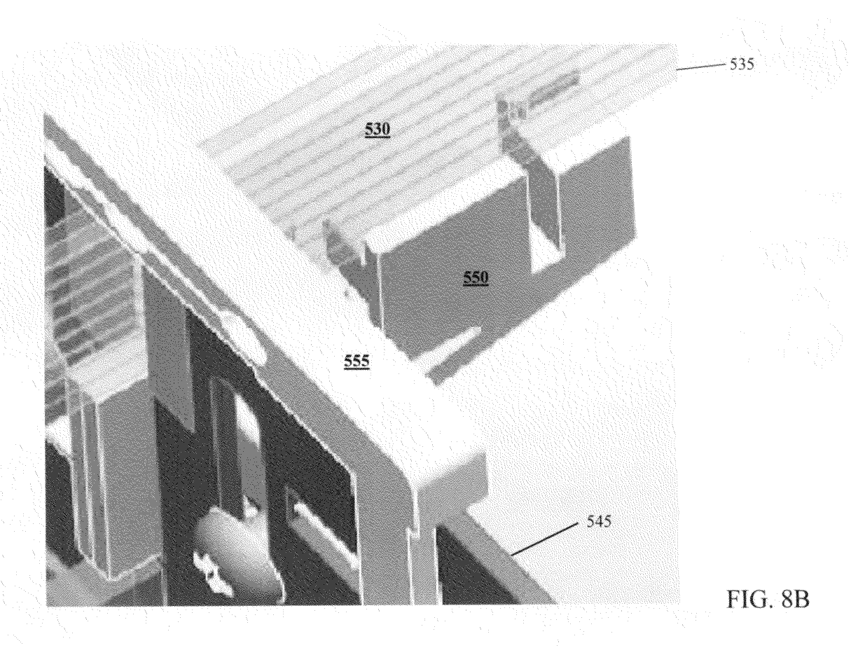

FIG. 8A depicts a single stage 570 of the solar concentrator. Wave-guide assembly 530 is shown mounted on riser assembly 540. Wave-guide segment support cradle 550 is mounted on riser base 545. Riser retention cap 555 is placed over the wave-guide assembly to hold it in place. Rise base 545 is attached to the frame of mirror assembly 510 (partially shown). Assembly alignment fixture 575 and its integral assembly alignment post 580 are mounted over mirror segment 515. Concentrated solar energy exits the end of the wave-guide assembly to illuminate a PVC assembly 560 (not shown) mounted at point 561.

FIG. 8B depicts details of wave-guide segment support cradle 550. Each wave-guide segment 535 is supported by a different wave-guide segment 535 below it. (Only the bottom segment is indicated.) The wave-guide segment at the bottom of wave-guide assembly 530 is supported by wave-guide support cradle 550. Wave-guide support cradle 550 is mounted on riser base 545. Riser retention cap 555 is placed over the wave-guide assembly to insure it remains in place during any movement of the solar concentrator assembly 500 (not shown).

FIG. 8B depicts wave-guide segment support cradle 550 as attached to only a single wave-guide segment 535. This enables wave-guide support cradle 550 to grasp wave-guide segment 535 and thereby control the position of turn mirror 520 (not shown) during thermal expansion and contraction of the various components of solar concentrator assembly 500. (not shown) Preferably the position of turn mirror 520 (not shown) does not move relative to the center of mirror segment 515. (not shown)

FIG. 8B depicts wave-guide segment support cradle 550 as being constructed from two assembly sections. This facilitates the manufacturing of the support cradle with support tabs extending vertically from the support arm, which in turn grasps wave-guide segment 535 immediately above it.

Those familiar with the physics of TIR will recognize that the points at which the wave-guide segments 535 of assembly 530 are touched by components of wave-guide segment support cradle 550 may cause the TIR condition not to be satisfied which in turn may cause some loss of concentrated solar radiation. Losses at these points can be minimized by affixing a reflective material such as silver or other suitable material to each wave-guide segment 535 at that point or to wave-guide segment support cradle 550 or to both.

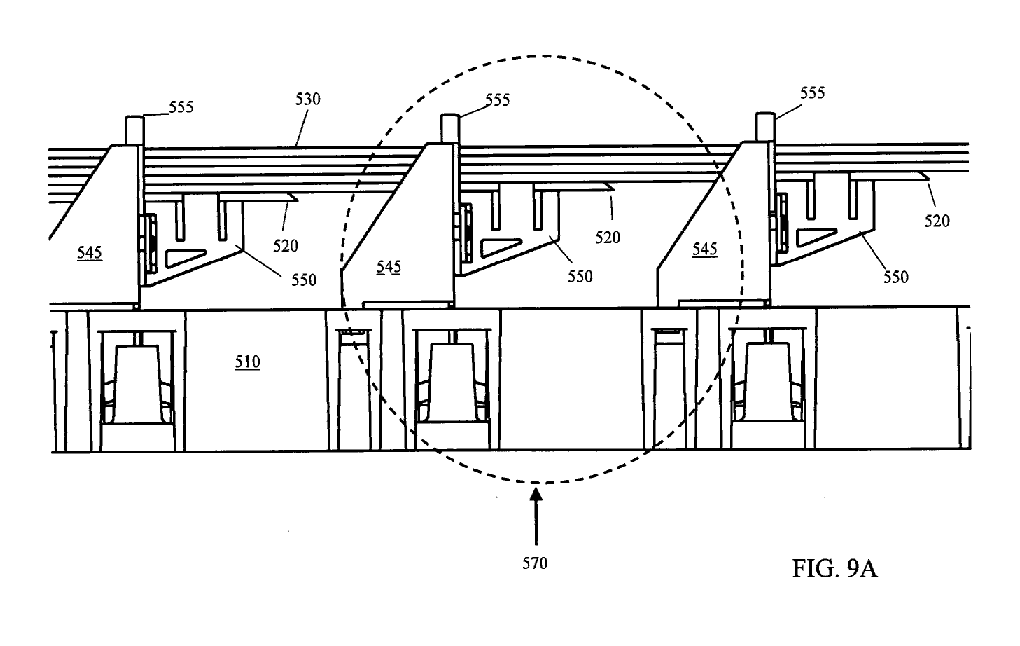

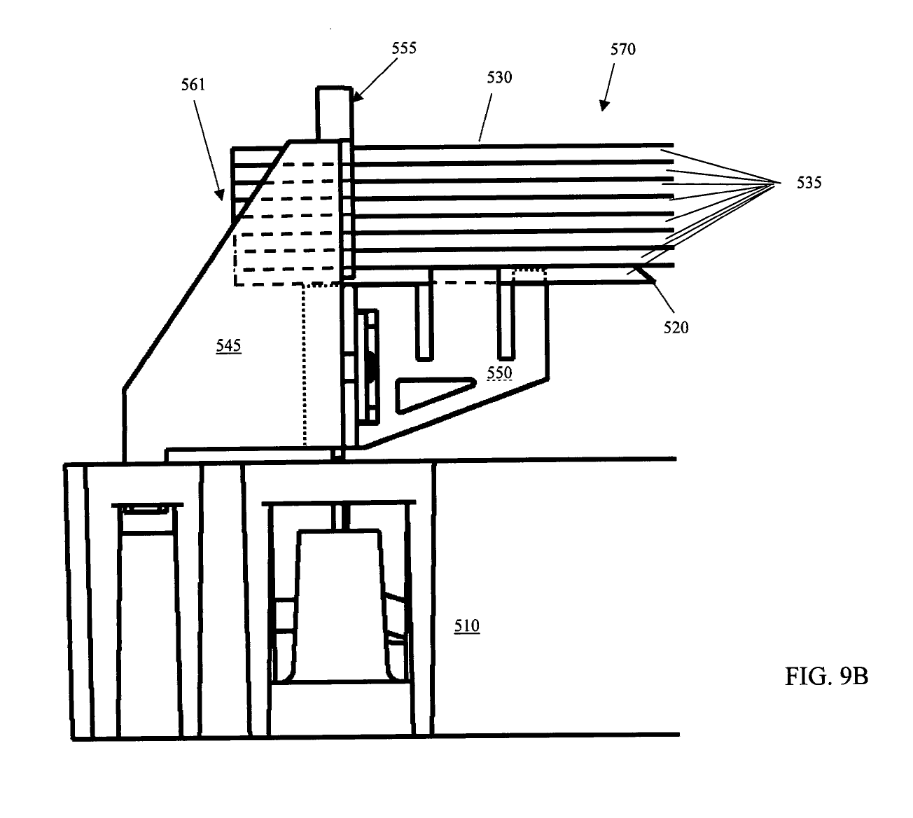

FIG. 9A depicts a side view of two stages 570 (one circled) of solar concentrator assembly 500 (not shown). Wave-guide assembly 530 is mounted over mirror assembly 510 such that turn mirror 520 is directly placed over the center of mirror segment 515 (not shown). Wave-guide assembly 530 is supported by wave-guide segment support cradle 550. Wave-guide segment support cradle is supported by riser base 545. Wave-guide assembly is held in place by riser retention cap 555.

FIG. 9B presents a partial view of a single stage 570 of a solar concentrator assembly 500 (not shown). Wave-guide assembly 530 is positioned over a mirror segment 515 (not shown) of mirror assembly 510 such that turn mirror 520 is positioned immediately over the center of mirror segment 515. Wave-guide segment support cradle 550 is attached to wave-guide segment 535 and is supported by riser base 545. Riser retention cap 555 holds wave-guide segments 535 of wave-guide assembly 530 in place.

FIG. 9B shows the layers (each wave guide segment 535) that comprise wave-guide assembly 530. Each wave-guide segment 535 is a separate wave-guide that propagates the solar radiation within it to the mounting point closest to photovoltaic cell assembly 600. Those familiar with the physics of TIR will recognize that some radiation may cross over from one wave-guide segment 535 to another. The wave-guide segments 535 are loosely coupled so crossover between segments can occur. Because of the random nature of any couplings it is expected that this will not adversely affect the uniformity of the concentrated solar radiation at PVC mounting point 561.

In an alternate embodiment of wave-guide assembly 530 the layers may be assembled by optical adhesive to form a single unit. The advantage is improved uniformity but the penalty is that the mirror assembly and the wave-guide assembly may be fabricated of materials with similar coefficients of thermal expansion in the designed thermal operating range. In another alternate embodiment the wave-guide assembly may be fabricated from a single piece of material.

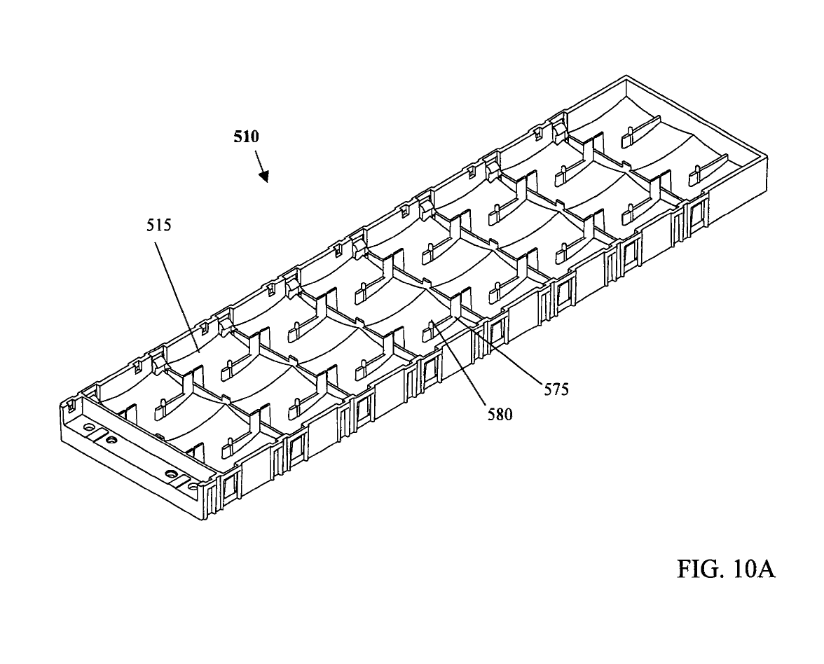

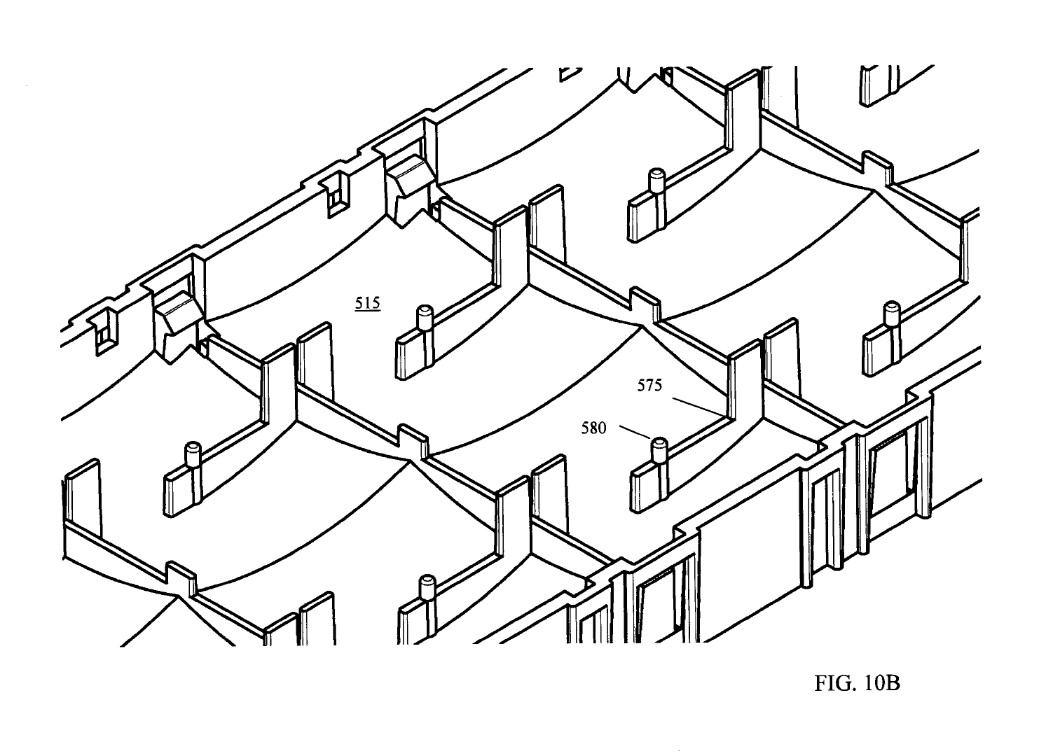

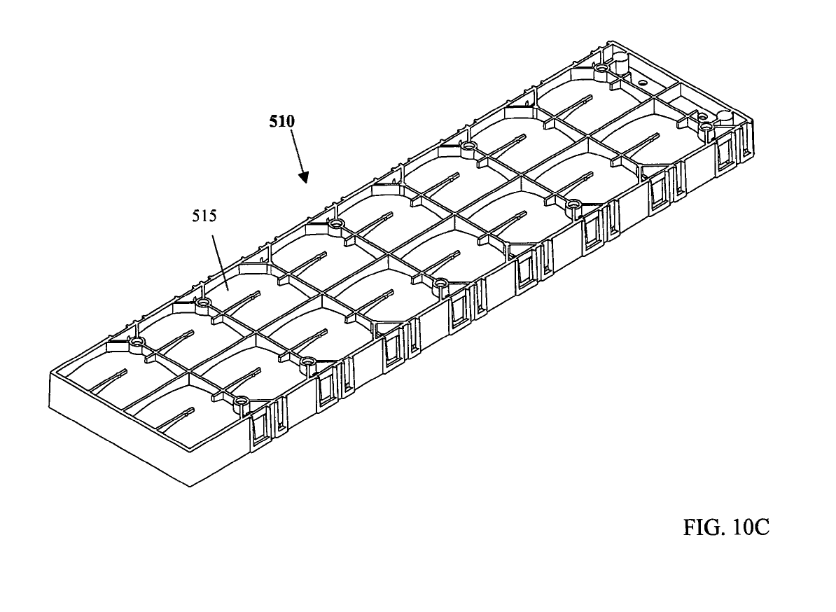

FIG. 10A presents an isometric view of a two-channel mirror assembly structure 510. Mirror assembly 510 comprises, in this figure, 16 mirror segments 515, and assembly alignment fixture 575, including assembly alignment post 580. Each mirror segment 515 is held in place by fixing means such as adhesive. In an alternate embodiment mirror assembly 510 is formed as a monolithic structure that comprise mirror segments 515, and assembly alignment fixture 575 including assembly alignment post 580. The mirror segments 515 on the structure may be coated by sputtering or by deposition. All components of upper side of the structure would thus have a reflective coating that would coincidentally reduce heating due to absorption.

FIG. 10B presents details of a part of mirror segments 515. Each mirror is surmounted by assembly alignment fixture 575, including assembly alignment post 580. By using assembly alignment fixture 575 and assembly alignment post 580 as part of the structure of the mirror assembly 510, the vertex of each mirror segment 515 is at a predetermined location relative to the alignment post.

FIG. 10C depicts a bottom view of mirror assembly 510. In the alternate embodiment identified in the teaching of FIG. 10A all elements shown in FIG. 10C represent a monolithic structure.

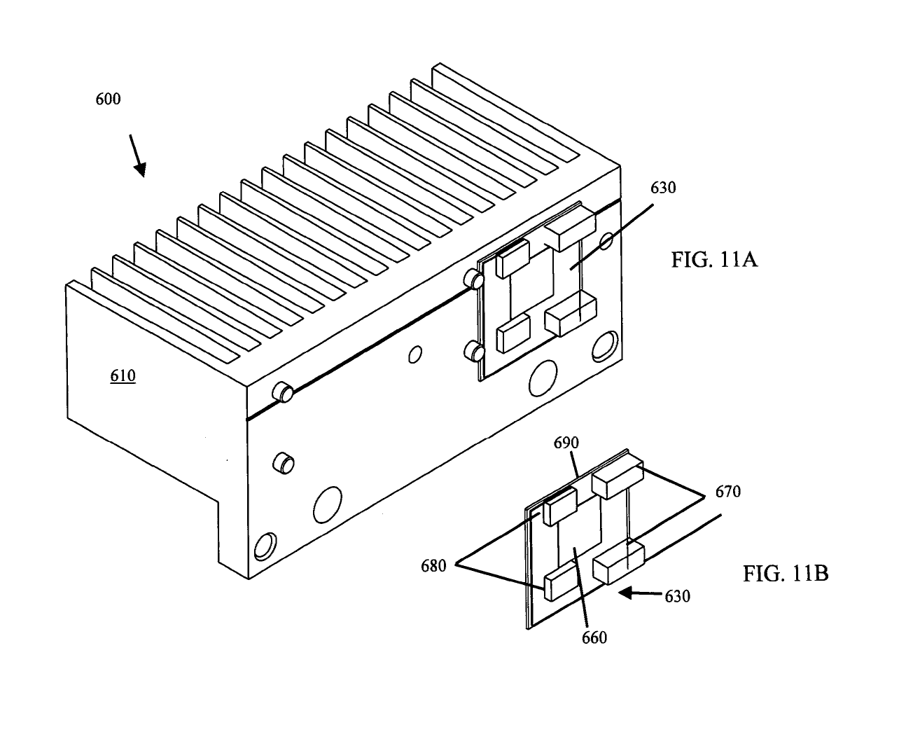

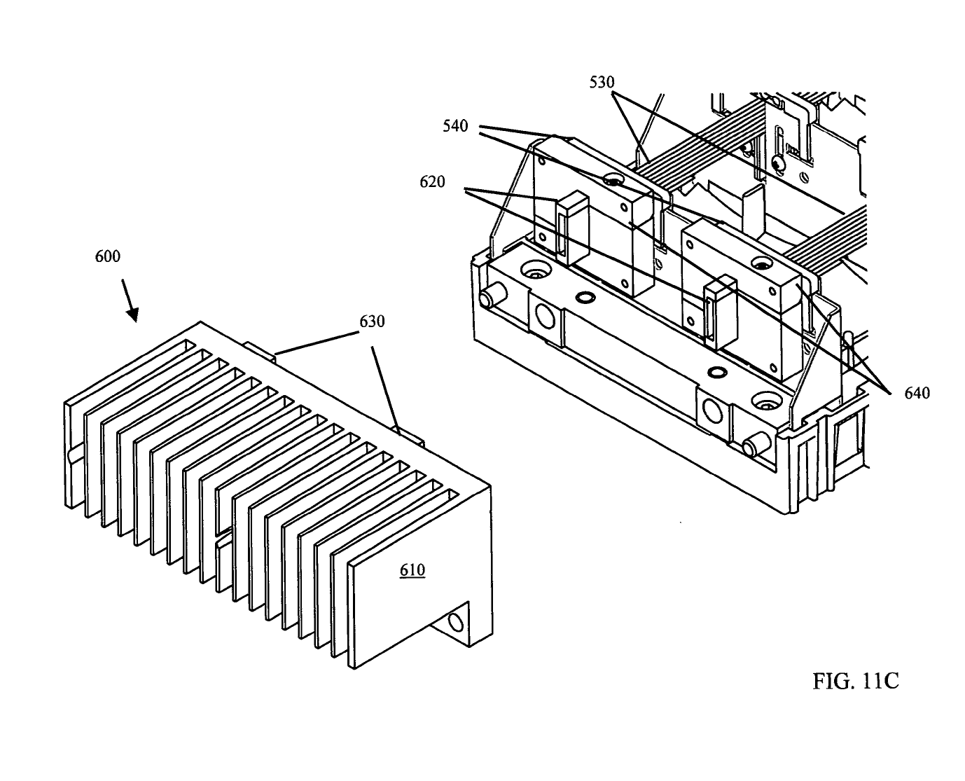

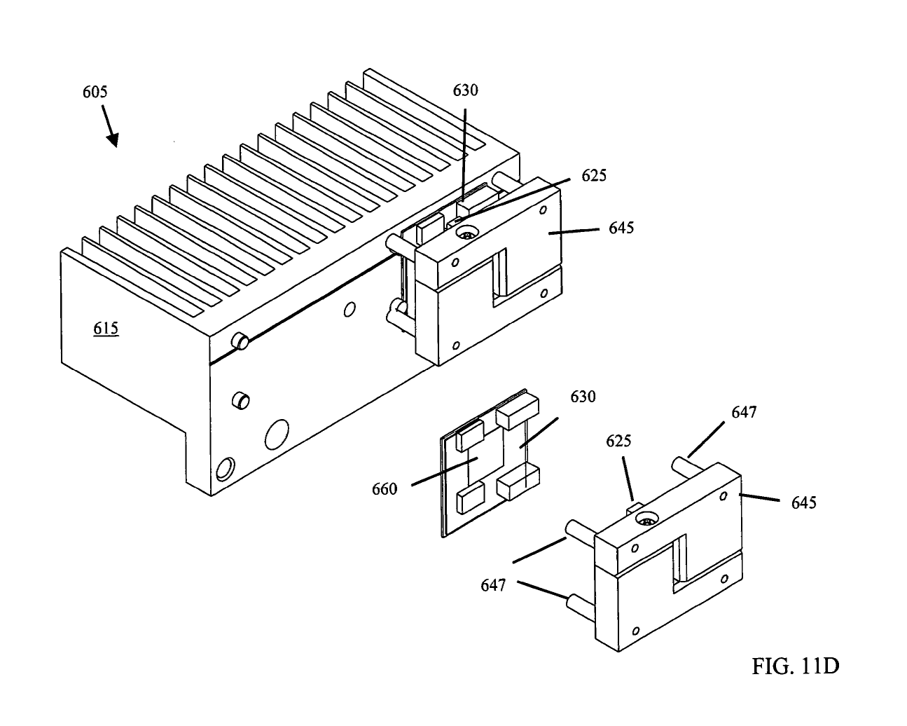

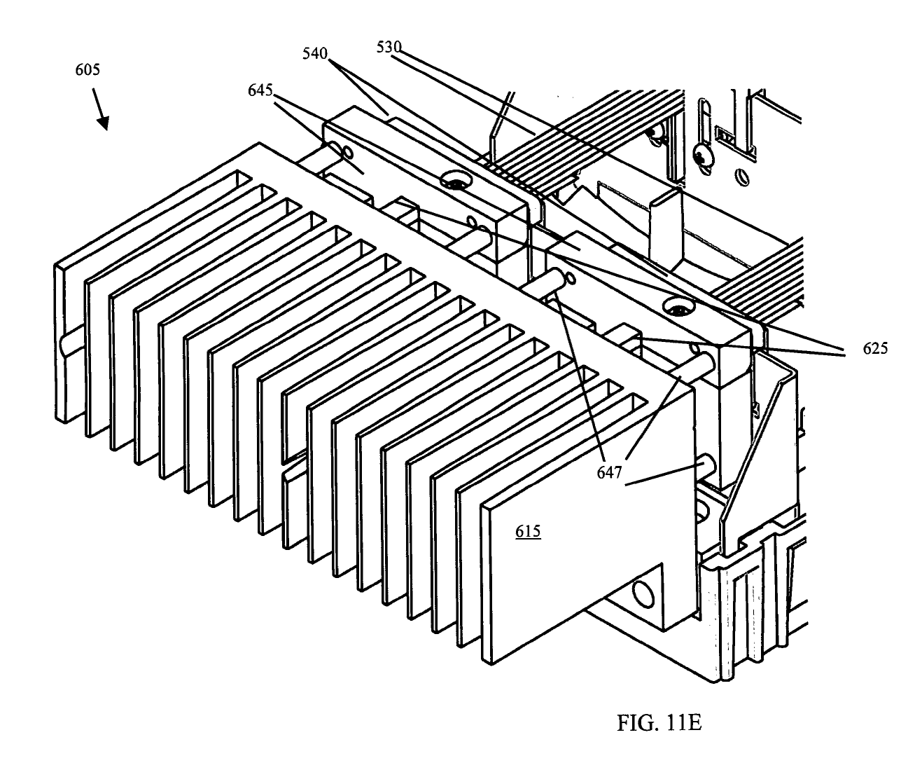

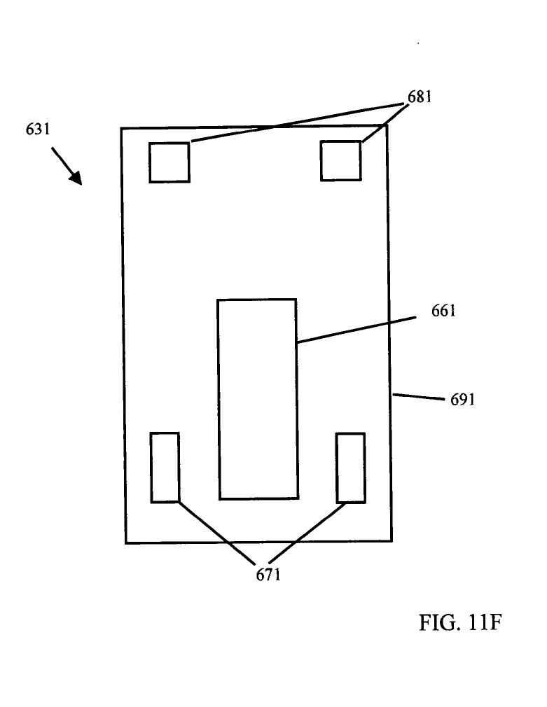

FIG.11A depicts photovoltaic cell assembly 600. Photovoltaic cell assembly 600 comprises heat sink 610 and photovoltaic cell subassembly 630 affixed thereto and second photovoltaic cell 630 subassembly brought forward for added detail. FIG. 11B depicts a photovoltaic cell subassembly 630 comprising photovoltaic cell 660, bypass diodes 670, cladded ceramic mounting 690 and electrical contacts 680. Photovoltaic cell assemblies similar to the depiction of FIG. 11B are available from several sources on a commercial basis.

FIG. 11C depicts photovoltaic cell assembly 600 aligned for mounting to solar concentrator assembly. Light tunnel 620 is affixed to riser assembly 540 by flange assembly 640 and the ends of wave-guide assembly 530 are aligned so that those ends terminate within light tunnel 620 to insure optimal capture of solar radiation. Photovoltaic cell 660 and photovoltaic cell subassembly 630 are constructed so that the exit end of light tunnel 620 is closely aligned with photovoltaic cell 660. Assembly may be facilitated by use of appropriately design alignment pins and the like as is well known in the art.

Those of ordinary skill in the art will recognize that a wave-guide of constant cross-section does not perform an angle transform upon solar radiation or any other form of light propagating within it in TIR mode and will recall that the range of angles present at the exit of the wave-guide will be the same as the range of angles of the solar radiation that enters it. For a crown glass material with an index of refraction of approximately 1.5 the critical angle (relative to the normal to the material) is 41.8°. Any solar radiation at an angle between 41.8° and 90° to the normal will remain at that angle until it leaves the wave-guide segment. Upon departing the wave-guide segment the beam is refracted to a far greater range of angles with the ultimate limit being 90°. The practical limit is the range of angles in the light reflected from the concentrator mirror relative to the normal to the wave-guide segment as modified by the turn mirror. Therefore as a matter of sound design practice it is important to limit any gaps between light tunnel 620 and photovoltaic cell subassembly 630 to the minimum practical distance.

FIG. 11D depicts another embodiment of a photovoltaic cell assembly 605. Photovoltaic cell assembly 605 comprises heat sink 615, photovoltaic cell subassembly 630 with photovoltaic cell 660 affixed thereto, light tunnel 625, flange mount 645 and support spacers 647. Photovoltaic cell subassembly 630 is affixed to heat sink 615 and light tunnel 625 is mated to flange assembly 645 which is in turn mated to heat sink 615 by support spacers 647. The light tunnel is aligned to insure efficient transfer of the solar radiation onto photovoltaic cell 660.

FIG. 11E presents a view of photovoltaic cell assembly 605 coupled to a solar concentrator assembly after the present invention. Wave-guide assembly 530 is routed through riser assembly 540 into light tunnel 620. Flange assembly 645 is mounted in close proximity to riser assembly with light tunnel 620 aligned with wave-guide assembly 530, thus enabling the capture of solar radiation.

FIG. 11F depicts an alternate photovoltaic cell subassembly 631. Photovoltaic cell subassembly 631 comprises photovoltaic cell 661, bypass diodes 671, electrical contacts 681 and ceramic substrate 691. Photovoltaic cell subassembly 631 offers improvements in two respects. Photovoltaic cell 661 is more closely matched to the dimensions and aspect ratio of the exit of light tunnel 620 and electrical contacts 681 are located above the level of the heat sink to facilitate wiring of the entire assembly after construction.

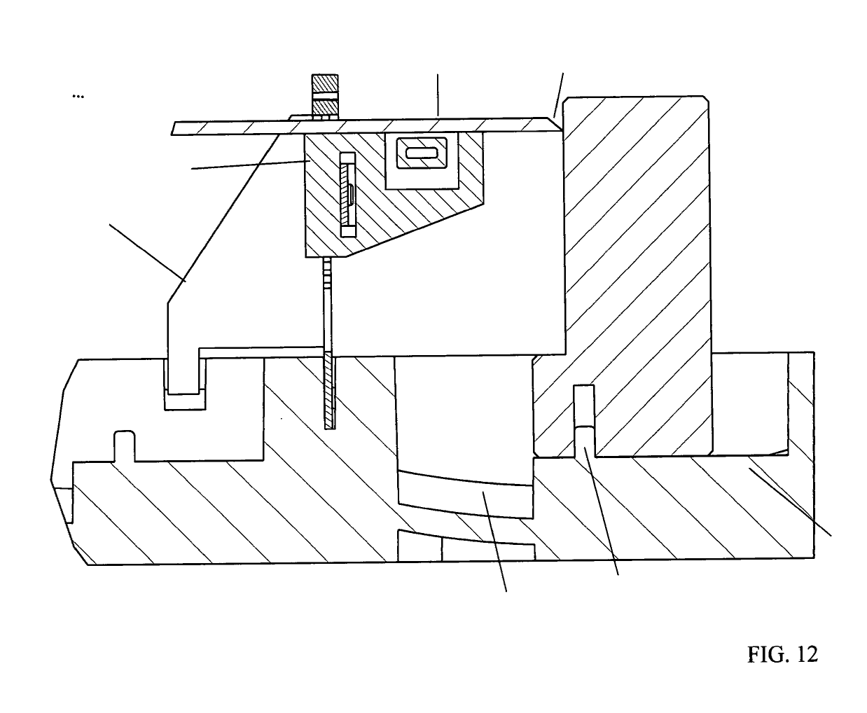

FIG. 12 depicts a means of aligning the turn mirror 520 to the proper point over mirror segment 515. Alignment jig 590 is inserted onto assembly alignment post 580 and assembly alignment fixture 575. Wave-guide segment 535 is then adjusted so that turn mirror 520 just touches alignment jig 590. Wave-guide segment 535 is supported by wave-guide segment support cradle 550. Wave-guide segment support cradle 550 is supported by riser base 545. Riser retention cap 555 is installed after all wave-guide segments 535 are installed and aligned.

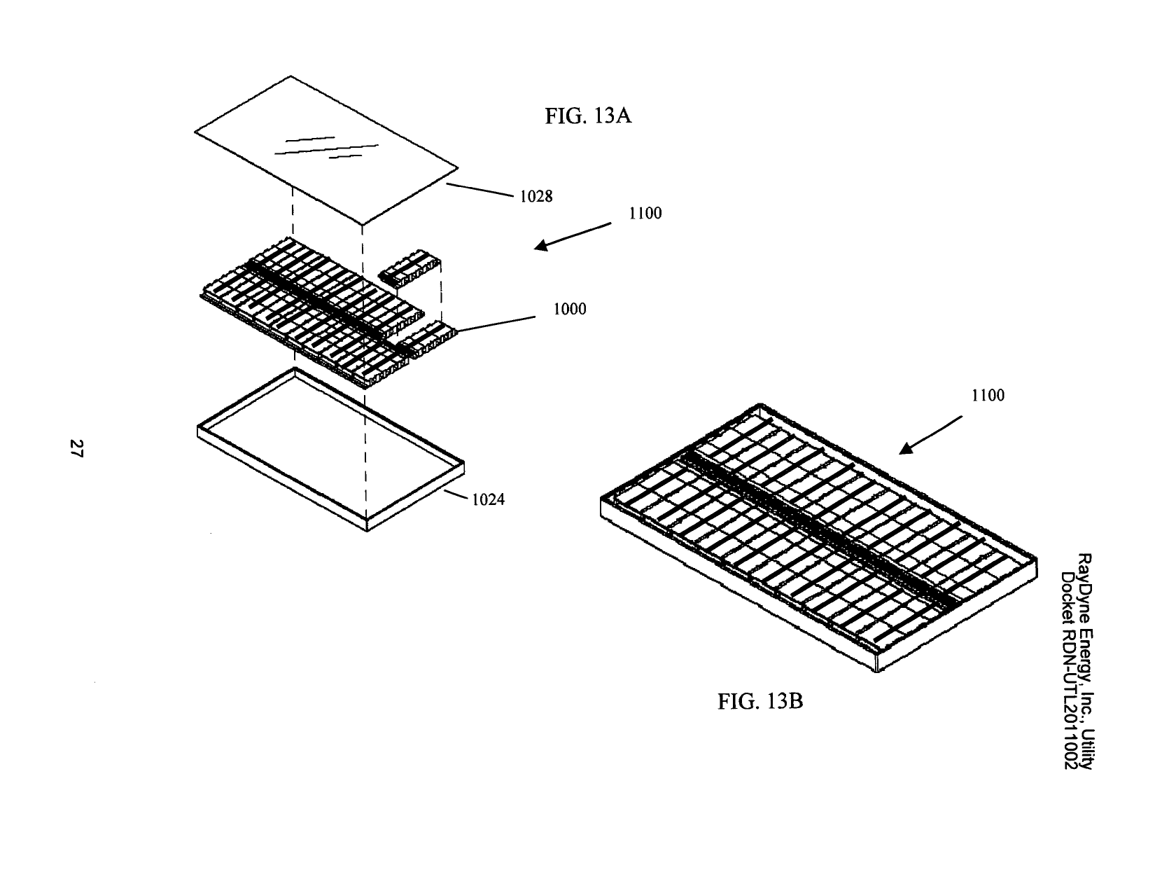

A practical solar energy system will require a significant number of solar energy concentrator assemblies similar to solar energy concentrator assembly 500 shown in FIG. 5 to produce sufficient electrical energy to be of economic value. FIG. 13A depicts an exploded isometric view of a unit of a solar concentrator system 1100 comprising a plurality of solar energy concentrator assemblies 1000 and its associate components to protect it from the elements. The plurality of solar energy concentrator assemblies is inserted into a weather cover frame 1024 and a transparent weather cover 1028 is attached thereto. FIG. 13B presents a weatherproof solar energy system unit 1100 based on the components of FIG. 5 and FIG. 13A. The individual solar concentrator assemblies are oriented such that the output of each photovoltaic cell is oriented along one axis at the center of the array, thus simplifying the wiring of the array.

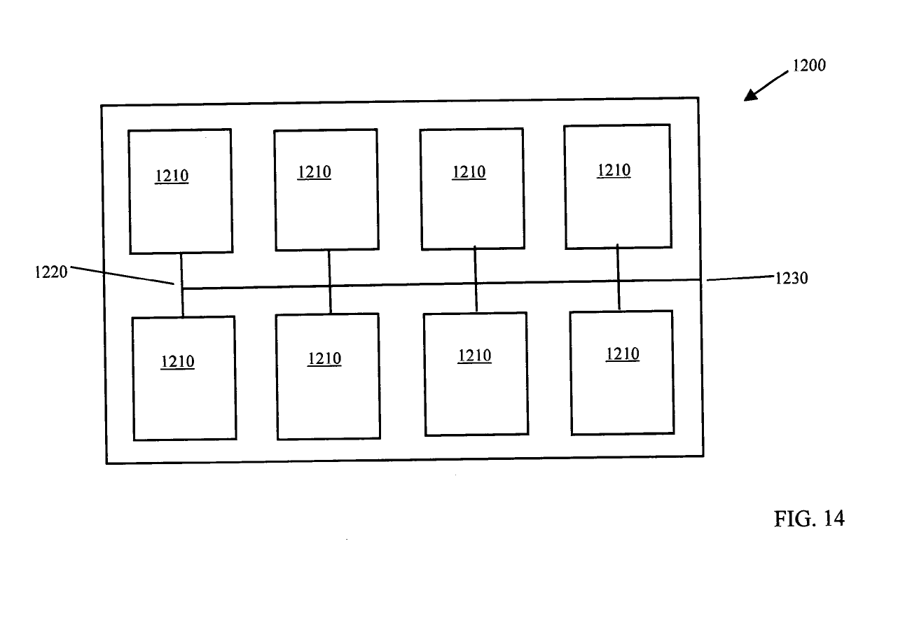

FIG. 14 depicts a simplified electrical diagram of a solar concentrator system unit comprising a plurality of solar concentrator assemblies 1210, connected by electrical connection system 1220 to external electrical output point 1230, located at the periphery of the weather cover frame 1024. Other locations would be obvious to those of ordinary skill in the art of optomechanical design. The PV cells of an individual solar concentrator assembly may be wired in series, parallel or a combination of the two. The combined output of a solar concentrator system unit may be wired in series, parallel or a combination of the two.

We claim:

1. A solar concentrator assembly comprising a mirror assembly comprising a plurality of mirror segments, a wave-guide assembly comprising a like number of wave-guide segments with turn mirrors affixed thereto, a light tunnel assembly and a photovoltaic cell assembly, and
Wherein said wave-guide assembly is substantially parallel to the longitudinal axis of the mirror assembly and wherein said wave-guide assembly is substantially centered over the transverse axis of said mirror assembly, and where said wave-guide assembly is positioned above said mirror assembly
Wherein said turn mirrors are disposed near the focal point of the mirror segments to receive reflected solar radiation from said mirror segments and convert said solar radiation to angles such that the solar radiation propagates within the wave-guide segments in TIR mode, and wherein said TIR may occur between any surfaces of said wave-guide segment, and
Wherein a light tunnel receives solar energy and relays said solar energy to a photovoltaic cell assembly disposed to receive solar energy from said light tunnel assembly and to convert said solar energy to electrical energy.

2. The solar concentrator assembly of claim 1 wherein the light tunnel assembly comprise a light tunnel and means for mounting said light tunnel

3. The solar concentrator assembly of claim 2 wherein the means for mounting the light tunnel is a flange assembly

4. The solar concentrator assembly of claim 3 wherein the light tunnel assembly is affixed to the photovoltaic cell assembly

5. The solar concentrator assembly of claim 3 wherein the light tunnel assembly is affixed to the mirror assembly???

6. The solar concentrator assembly of claim 1 wherein the photovoltaic cell comprises a heat sink and a photovoltaic cell affixed to said heat sink

7. The solar concentrator assembly of claim 6 wherein the photovoltaic cell comprises a heat sink, a photovoltaic cell affixed to the heat sink, a light tunnel affixed to a mounting flange, said mounting flange affixed by mounting means to the heat sink.

8. The solar concentrator assembly of claim 1 wherein the turn mirror is disposed on an angled surface, said angle being approximately 45 degrees to the upper and lower surface of a wave-guide segment with the longer side disposed closer to the concentrator mirror assembly.

9. The solar concentrator assembly of claim 8 wherein the turn mirror is formed by a coating on the angled surface.

10. The solar concentrator assembly of claim 8 wherein the turn mirror is a separate mirror affixed in close proximity to the angled surface with an air gap between said angle surface and said mirror.

11. The solar concentrator assembly of claim 1 wherein the turn-mirror is disposed on an angled surface, said angle being approximately 30 degrees to the upper and lower surface of a wave-guide segment with the longer side closest to the concentrator mirror assembly.

12. The solar concentrator assembly of claim 11 wherein the turn-mirror is formed by a coating on the angled surface.

13. The solar concentrator assembly of claim 11 wherein the turn mirror is a separate mirror affixed in close proximity to the angled surface with an air gap between said angle surface and said mirror.

14. The solar concentrator assembly of claim 1 wherein the turn-mirror comprises a dielectric coating.

15. The solar concentrator assembly of claim 1 wherein the wave-guide assembly comprises a monolithic assembly with a plurality of turn mirrors.

16. The solar concentrator assembly of claim 1 wherein the mirror assembly comprises a plurality of separate concentrator mirrors.

17. The solar concentrator assembly of claim 1 wherein the mirror assembly comprises a monolithic structure including concentrator mirrors and assembly frame.

18. The solar concentrator assembly of claim 1 wherein the wave-guide assembly comprises a plurality of wave-guide segments. (redundant to claim 15?)

19. The solar concentrator assembly of claim 19 wherein the wave-guide assembly and the concentrator mirror assembly are fabricated from materials with substantially different coefficients of thermal expansion.

20. The solar concentrator assembly of claim 19 wherein the wave-guide segments are held by a support assembly that maintain substantial optical alignment between the turn mirror affixed to the wave-guide segment and the concentrator mirror segment associated with it over a range of operating temperatures.

21. A solar concentrator system unit comprising:
A plurality of solar concentrator assemblies each comprising a mirror assembly comprising a plurality of mirror segments, a wave-guide assembly comprising a like number of wave-guide segments with turn mirrors affixed thereto, a light tunnel assembly and a photovoltaic cell assembly, and
Wherein said wave-guide assembly is substantially parallel to the longitudinal axis of the mirror assembly and wherein said wave-guide assembly is substantially centered over the transverse axis of said mirror assembly, and where said wave-guide assembly is positioned above said mirror assembly
Wherein said turn mirrors are disposed near the focal point of the mirror segments to receive reflected solar radiation from said mirror segments and convert said solar radiation to angles such that the solar radiation propagates within the wave-guide segments in TIR mode, and wherein said TIR may occur between any surfaces of said wave-guide segment, and
Wherein a light tunnel receives solar energy and relays said solar energy to a photovoltaic cell assembly disposed to receive solar energy from said light tunnel assembly and to convert said solar energy to electrical energy, and
Said solar concentrator system unit further comprising a wiring assembly to connect the electrical energy thereby gathered to a suitable external point of the solar concentrator system unit.

22. The solar concentrator system unit of claim 21 wherein the suitable external electrical connection point is on the periphery of a weather cover frame.

23. The solar concentrator system of claim 21 wherein the wiring assembly connects the solar concentrator assemblies to the external electrical connection point in series.

24. The solar concentrator system of claim 21 wherein the wiring assembly connects the solar concentrator assemblies to the external electrical connection point in parallel.
